(19) United States
(12) Patent Application Publication
(10) Pub. No.: US 2026/0005155 A1
(43) Pub. Date: Jan. 1, 2026

(54) PACKAGE STRUCTURE WITH ELECTROMAGNETIC SHIELDING FUNCTIONALITY

(71) Applicant: JCET Group Co. Ltd., Jiangsu (CN)

(72) Inventors: Xianfang YANG, Jiangsu (CN); Peng LI, Jiangsu (CN); Junjun LI, Jiangsu (CN); Yuhao LIU, Jiangsu (CN)

(73) Assignee: JCET Group Co. Ltd., Jiangsu (CN)

(21) Appl. No.: 19/245,876

(22) Filed: Jun. 23, 2025

(30) Foreign Application Priority Data
Jun. 26, 2024 (CN) 202410836159.0

(51) Int. Cl. H01L 23/552; H01L 23/00; H01L 23/498; H01L 25/065

(52) U.S. Cl. CPC H01L 23/552; H01L 23/49811; H01L 23/49838; H01L 24/16; H01L 25/0655; H01L 2224/16227

(57) ABSTRACT

A package structure with electromagnetic shielding functionality includes: a substrate; a chip, disposed on a surface of the substrate; a conductive dam, disposed on the surface of the substrate and grounded, the conductive dam surrounding a periphery of the chip; a plurality of wires, disposed on the conductive dam; a molding body, covering the surface of the substrate and encapsulating the chip, the conductive dam, and the wires, wherein a portion of each of the wires is exposed on a surface of the molding body; and a conductive layer, positioned outside the molding body and at least corresponding to the chip, wherein the conductive layer is electrically connected to the wires, and the conductive layer, the wires, and the conductive dam together form a Faraday cage surrounding the chip.

### CROSS-REFERENCE TO RELATED APPLICATION

The present application is based upon and claims priority to Chinese Application No. 202410836159.0, filed on Jun. 26, 2024, all disclosures of which are incorporated herein by reference in their entirety for all purposes.

### TECHNICAL FIELD

The present disclosure relates to the technical field of semiconductor packaging, and in particular, relates to a package structure with electromagnetic shielding functionality.

### BACKGROUND

Electromagnetic interference (EMI) refers to any electromagnetic phenomenon that occurs through conduction or as a result of an electromagnetic field associated with voltage or current, which may impair the performance of a device, an equipment, or a system, and may also have detrimental effects on living organisms or materials. As board-level and package-level electronic systems continue to evolve towards low voltage, high power consumption, high density, and high speed, signal integrity, power integrity, and electromagnetic compatibility have become key research subjects in high-speed circuit design and system-level packaging. For example, with respect to a radio frequency (RF) package structure, as the operating frequency of RF modules or devices increases and products become smaller, the harm caused by the EMI becomes more significant. When RF modules or adjacent RF devices are subjected to the EMI, reduced lifespan, signal degradation, and even loss of functionality may be caused.

Electromagnetic shielding is commonly used to reduce or effectively isolate the EMI in package structures. Typically, a grounded metal shield or metal shielding film is placed around the periphery of a chip that needs shielding. The metal shield or film absorbs unwanted EMI signals and converts the EMI signals into grounded conductive currents, thereby preventing RF radiation and shielding the EMI.

### SUMMARY

The technical problem to be solved by the present disclosure is to provide a package structure with electromagnetic shielding functionality, which prevents wire bond tilt or misalignment, and thus improves the reliability of the package structure and the electromagnetic shielding performance.

Accordingly, some embodiments of the present disclosure provide a package structure with electromagnetic shielding functionality. The package structure includes: a substrate; a chip, disposed on a surface of the substrate a conductive dam, disposed on the surface of the substrate and grounded, the conductive dam surrounding a periphery of the chip; a plurality of wires, disposed on the conductive dam; a molding body, covering the surface of the substrate and encapsulating the chip, the conductive dam, and the wires, wherein a portion of each of the wires is exposed on a surface of the molding body; and a conductive layer, positioned on the surface of the molding body and at least corresponding to the chip, wherein the conductive layer is electrically connected to the wires, and the conductive layer, the wires, and the conductive dam together form a Faraday cage surrounding the chip.

In some embodiments, the conductive dam is a continuous structure.

In some embodiments, the conductive dam is a discontinuous structure including a plurality of sub-dams spaced apart, wherein the wires are disposed on the sub-dams.

In some embodiments, the sub-dams have identical or different sizes.

In some embodiments, gaps between adjacent sub-dams are identical or different.

In some embodiments, the chip is flip-mounted onto the surface of the substrate via conductive pillars, and a height of the conductive dam is less than a height of the conductive pillars.

In some embodiments, the wires include arcuate wires, wherein both ends of each of the arcuate wires are connected to the conductive dam, and a portion of the each of the arcuate wires, along an extension path thereof, is exposed on the surface of the molding body.

In some embodiments, a plurality of the arcuate wires are arranged in a circumferential direction surrounding the chip to form a single wire layer.

In some embodiments, a plurality of the arcuate wires are arranged in a circumferential direction surrounding the chip to form at least two wire layers, and adjacent arcuate wires in two adjacent wire layers are arranged to be intersected with each other.

In some embodiments, the wires include vertical wires extending in a direction perpendicular to the substrate, wherein one end of each of the vertical wires is connected to the conductive dam, and the other end of the each of the vertical wires is exposed on the surface of the molding body.

In some embodiments, the wires include arcuate wires, wherein both ends of each of the arcuate wires are connected to the conductive dam, and a portion of the each of the arcuate wires, along an extension path thereof, is exposed on the surface of the molding body, and the vertical wires are disposed to be intersected with the arcuate wires.

In some embodiments, each of the vertical wires has a bent portion along an extension path thereof.

In some embodiments, the conductive dam is grounded via the substrate.

In the package structure with electromagnetic shielding functionality according to the embodiments of the present disclosure, the conductive layer disposed above the chip, the wires disposed on a side of the chip, and the conductive dam together form a Faraday cage around the chip. A side of the Faraday cage is not solely formed by the wires, but by a combination of the conductive dam and the wires. The sum of the heights of the conductive dam and the wires constitutes the height of the Faraday cage. Compared to a package structure where the side of the Faraday cage is solely made of wires, the package structure according to the embodiments of the present disclosure reduces the height of the wires, which fundamentally improves the stability of the wires, prevents issues such as short circuits and open circuits caused by wire tilt or misalignment, and significantly improves the reliability and electromagnetic shielding performance of the package structure.

### BRIEF DESCRIPTION OF THE DRAWINGS

For clearer descriptions of the technical solutions according to the embodiments of the present disclosure, hereinafter brief description is given with reference to the accompanying drawings for illustrating the embodiments. Apparently, the accompanying drawings described hereinafter only illustrate some embodiments of the present disclosure, and other accompanying drawings may also be derived by persons of ordinary skill in the art based on these accompanying drawings without any creative effort.

FIG. 1 is a schematic diagram of a conventional package structure with electromagnetic shielding functionality;

FIG. 2 is a schematic diagram of a package structure with electromagnetic shielding functionality according to some embodiments of the present disclosure;

FIG. 3 is a schematic top view illustrating relative positions of a conductive dam, wires, and a chip in the package structure with electromagnetic shielding functionality according to some embodiments of the present disclosure;

FIG. 4 is a schematic side view illustrating relative positions of a conductive dam and wires in the package structure with electromagnetic shielding functionality according to some embodiments of the present disclosure;

FIG. 5 is a schematic top view illustrating relative positions of a conductive dam, wires, and a chip in a package structure with electromagnetic shielding functionality according to some embodiments of the present disclosure;

FIG. 6 is a schematic top view illustrating relative positions of a conductive dam, wires, and a chip in a package structure with electromagnetic shielding functionality according to some embodiments of the present disclosure;

FIG. 7 is a schematic side view illustrating relative positions of a conductive dam and wires in the package structure with electromagnetic shielding functionality according to some embodiments of the present disclosure;

FIG. 8 is a schematic top view illustrating relative positions of a conductive dam, wires, and a chip in a package structure with electromagnetic shielding functionality according to some embodiments of the present disclosure;

FIG. 9 is a schematic side view illustrating relative positions of a conductive dam and wires in the package structure with electromagnetic shielding functionality according to some embodiments of the present disclosure;

FIG. 10 is a schematic diagram of wires in a package structure with electromagnetic shielding functionality according to some embodiments of the present disclosure; and

FIG. 11 is a schematic side view illustrating relative positions of a conductive dam and wires in the package structure with electromagnetic shielding functionality according to some embodiments of the present disclosure.

### DETAILED DESCRIPTION

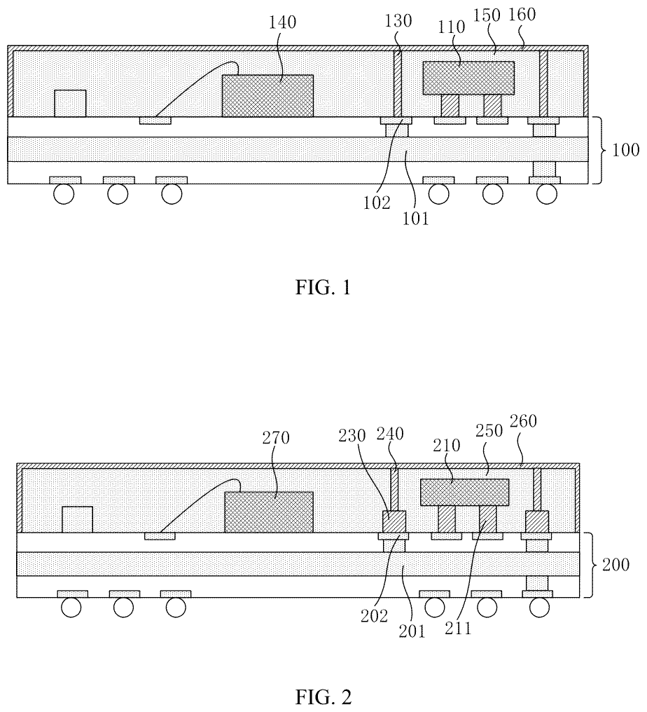

FIG. 1 is a schematic diagram of a conventional package structure with electromagnetic shielding functionality. Referring to FIG. 1, a chip 110 that requires electromagnetic shielding is provided on a surface of a substrate 100; a conductive grounding layer 101 is disposed in the substrate 100; a solder pad 102 is disposed on the surface of the substrate 100, wherein the solder pad 102 is electrically connected to the conductive grounding layer 101, a wire bond 130 is disposed around a periphery of the chip 110 on the surface of the substrate 100, wherein the wire bond 130 is electrically connected to the solder pad 102; and a conductive layer 160 is disposed on a surface of a molding body 150 that covers the wire bond 130 and the chip 110, wherein the conductive layer 160 is electrically connected to the wire bond 130. The conductive layer 160, the wire bond 130, and the conductive grounding layer 101 together form a Faraday cage to address the issue of EMI between chip 110 and other surrounding elements or devices (e.g., a chip 140 adjacent to chip 110). However, for package structures with a larger package thickness, such as RF module package structures, the overall package thickness is generally around 0.5 mm. This requires the height of the wire bond 130 to be greater than 0.5 mm. As the height of the wire bond 130 increases, the stability of the wire bond 130 decreases, and the wire bond 130 is more likely to tilt or misalign, which potentially causes the wire bond 130 to come into contact with an edge of the adjacent chip 110 or another wire bond 130, resulting in short circuits. Additionally, the tilted wire bond 130 may not be exposed in a case where the molding body is thinned, meaning the wire bond 130 is not exposed on a surface of the molding compound 150. As a result, the wire bond 130 may fail to come in contact with the conductive layer 160 on the surface of the molding body 150, which causes open circuits and affects the electromagnetic shielding performance.

Some specific embodiments of a package structure with electromagnetic shielding functionality according to the present disclosure are described in detail hereinafter with reference to the accompanying drawings.

FIG. 2 is a schematic diagram of a package structure with electromagnetic shielding functionality according to some embodiments of the present disclosure. Referring to FIG. 2, the package structure includes: a substrate 200; a chip 210, disposed on a surface of the sub strate 200; a conductive dam 230, disposed on the surface of the substrate 200 and grounded, the conductive dam 230 surrounding a periphery of the chip 210; a plurality of wires (for example, arcuate wires 240), disposed on the conductive dam 230; a molding body 250, covering the surface of the substrate 200 and encapsulating the chip 210, the conductive dam 230, and the wires, wherein a portion of each of the wires is exposed on a surface of the molding body 250; and a conductive layer 260, positioned on the surface of the molding body 250 and at least corresponding to the chip 210, wherein the conductive layer 260 is electrically connected to the wires, and the conductive layer 260, the wires, and the conductive dam 230 together form a Faraday cage surrounding the chip 210.

In the package structure with electromagnetic shielding functionality according to the embodiments of the present disclosure, the conductive layer 260 disposed above the chip 210, the wires disposed on a side of the chip 210, and the conductive dam 230 together form a Faraday cage around the chip 210. A side of the Faraday cage is not solely formed by the wires, but by a combination of the conductive dam 230 and the wires. The sum of the heights of the conductive dam 230 and the wires constitutes the height of the Faraday cage. Compared to a package structure where the side of the Faraday cage is solely made of wires, the package structure according to the embodiments of the present disclosure reduces the height of the wires, which fundamentally improves the stability of the wires, prevents issues such as short circuits and open circuits caused by wire tilt or misalignment, and significantly improves the reliability and electromagnetic shielding performance of the package structure.

A Faraday cage is a shell made of a good electrical conductor that prevents electromagnetic fields (EM fields) from entering or escaping. The Faraday cage prevents electromagnetic waves outside the Faraday cage from interfering with the chip 210 inside, and also prevents electromagnetic waves from the chip 210 inside the Faraday cage from emitting outward and interfering with the normal operation of other devices. In the embodiments of the present disclosure, the chip 210 is a chip that requires electromagnetic shielding. For example, in some embodiments, the chip 210 is an RF chip, and the RF chip is positioned inside the Faraday cage, such that electromagnetic waves outside the Faraday cage are prevented from interfering with the RF chip. At the same time, the electromagnetic waves from the RF chip are also prevented from being emitted outward and interfering with the normal operation of other devices within the package structure (for example, another chip 270 adjacent to the RF chip).

In some embodiments, the chip 210 is flip-chip mounted on the surface of the substrate 200 and is electrically connected to the substrate 200 via conductive pillars 211. Specifically, as illustrated in FIG. 2, the chip 210 is flip-chip mounted on the surface of the substrate 200 via the conductive pillars 211. In these embodiments, the height of the conductive dam 230 is less than the height of the conductive pillars 211. During packaging, in the cleaning step subsequent to mounting and reflow soldering of the chip 210, a cleaning fluid may be smoothly drained as the height of the conductive dam 230 is less than that of the conductive pillar 211, which facilitates the cleaning process.

In the package structure, the conductive layer 260 disposed above the substrate 200, the wires, and the conductive dam 230 together form a Faraday cage surrounding the chip 210. The conductive dam 230 is grounded, such that the Faraday cage is grounded. In some embodiments, the conductive dam 230 is grounded via the substrate 200. Specifically, a conductive grounding layer 201 is disposed within the substrate 200, and a pad 202 electrically connected to the grounding conductive layer 260 is disposed on the surface of the substrate 200. The conductive dam 230 is disposed on the pad 202, and thus electrically connected to the conductive grounding layer 201 via the pad 202, such that the Faraday cage is grounded. In some other embodiments, the conductive dam 230 may also be grounded via a redistribution layer (RDL) disposed on the surface of the substrate 200.

The conductive dam 230 may be either a discontinuous structure or a continuous structure that surrounds the periphery of the chip 210. In a case where the conductive dam 230 is a discontinuous structure, the conductive dam 230 includes a plurality of sub-dams spaced apart, wherein the wires are disposed on the sub-dams. In some embodiments, a width of an upper surface of the conductive dam 230 is the same as a width of the pad 202 to prevent the upper surface of the conductive dam 230 from being too narrow. A too narrow upper surface may affect the subsequent formation of the wires.

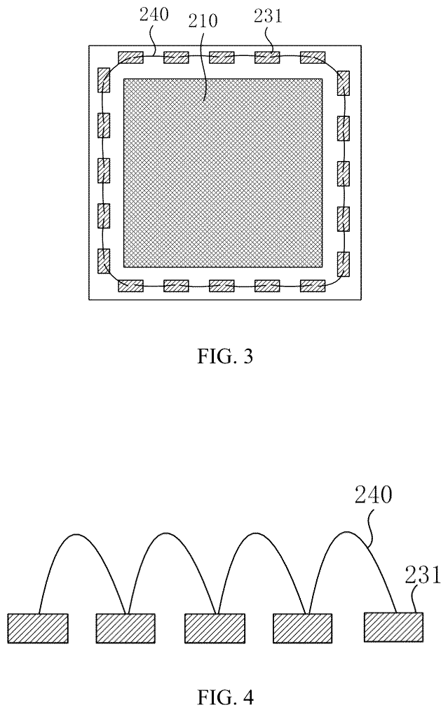

Specifically, as illustrated in FIG. 3, which is a top view illustrating relative positions of the conductive dam 230, the wires, and the chip 210 in the package structure according to some embodiments of the present disclosure, the conductive dam 230 in these embodiments is a discontinuous structure that surrounds the periphery of the chip 210. The conductive dam 230 includes a plurality of sub-dams 231, which are spaced apart around the periphery of the chip 210. The wires are disposed on the sub-dams 231. Dimensions of the sub-dams 231 may be the same or different, wherein the dimensions of the sub-dam 231 refer to at least one of its length, width, or height. In some embodiments, to simplify the process, the heights of all the sub-dams 231 are the same. A gap is present between two adjacent sub-dams 231. During packaging, in the cleaning step subsequent to mounting and reflow soldering of the chip 210, the cleaning fluid may flow out through the gap, which facilitates the cleaning process. A size of the gap needs to meet the requirements for formation of the Faraday cage. Where the gap is too large, a Faraday cage may not be formed. In some embodiments, the gaps between adjacent sub-dams 231 are identical or different.

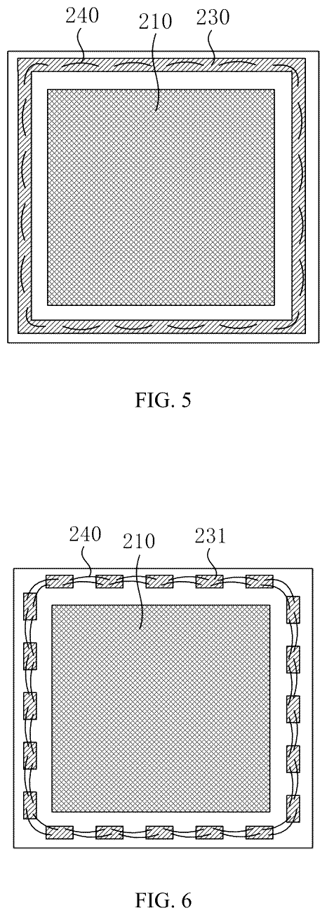

As illustrated in FIG. 5, a top view illustrating relative positions of the conductive dam, wires, and chip in the package structure with electromagnetic shielding functionality according to some embodiments of the disclosure is given. In these embodiments, the conductive dam 230 is a continuous structure surrounding the periphery of the chip 210, that is, the conductive dam 230 is a closed structure disposed around the periphery of the chip 210, which further enhances the electromagnetic shielding performance of the Faraday cage.

The wires are disposed on the conductive dam 230, with a plurality of wires arranged around the periphery of the chip 210. The conductive dam 230 and the wires together form sidewalls of the Faraday cage. The wires may be secured to the conductive dam 230 by a wire bonding process.

In some embodiments, the wires include arcuate wires 240, wherein both ends of each of the arcuate wires 240 are connected to the conductive dam 230, and a portion of the each of the arcuate wires 240, along an extension path thereof, is exposed on the surface of the molding body 250. Specifically, referring to FIG. 2 to FIG. 4, where FIG. 4 is a side view illustrating relative positions of the conductive dam and the wires, in some embodiments, the conductive dam 230 includes a plurality of sub-dams 231 spaced apart. One end of the arcuate wire 240 is disposed on one sub-dam 231, and the other end of the arcuate wire 240 is disposed on another sub-dam 231. In other embodiments, one end of the arcuate wire 240 is disposed on one sub-dam 231, and the other end of the arcuate wire 240 may also be disposed on the same sub-dam 231, that is, the arcuate wire 240 may be connected to the same sub-dam 231 or to different sub-dams 231. Along an extension path of the arcuate wire 240, a portion of the arcuate wire 240, for example, a top region, is exposed on the surface of the molding body 250. The conductive layer 260 on the surface of the molding body 250 is in contact with and electrically connected to the top region, thereby achieving electrical connection between the wire and the conductive layer 260. The extension path of the arcuate wire 240 refers to a path traversed by the arcuate wire 240.

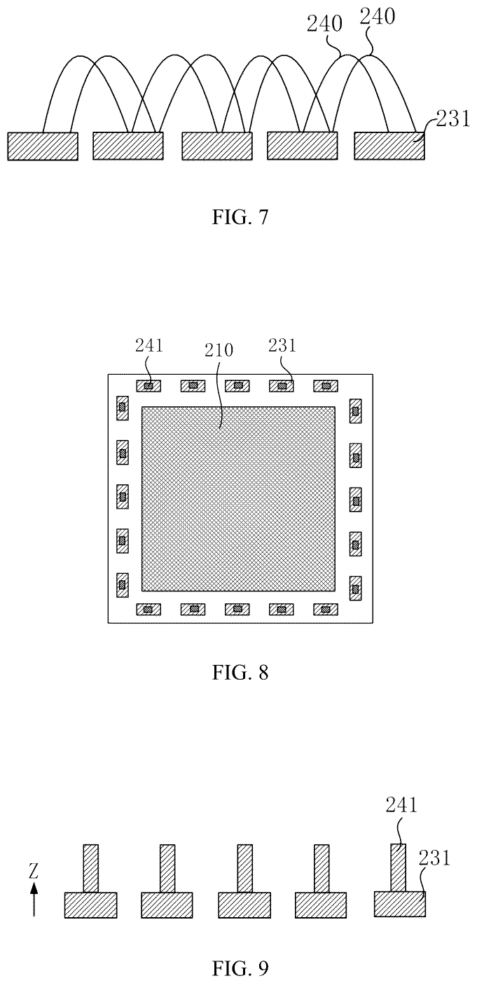

In some embodiments, a plurality of arcuate wires 240 are arranged in a circumferential direction surrounding the chip 210, forming a single layer of wire. In some other embodiments, a plurality of arcuate wires 240 are arranged in the circumferential direction surrounding the chip 210 and form at least two layers of wires. Adjacent wires in the two layers are disposed to be intersected each other, thereby providing mutual support, and further enhancing the stability of the wires and preventing wire tilt or misalignment. Specifically, FIG. 6 is a top view illustrating relative positions of a conductive dam, wires, and a chip in a package structure with electromagnetic shielding functionality according to some embodiments of the present disclosure, and FIG. 7 is a side view illustrating relative positions of a conductive dam and wires in the package structure with electromagnetic shielding functionality according to some embodiments. As illustrated in FIG. 6 and FIG. 7, in these embodiments, a plurality of arcuate wires 240 are arranged in the circumferential direction surrounding the chip 210 and form two layers of wires. Adjacent arcuate wires in the two layers are disposed to be intersected with each other, for example, one end of an arcuate wire 240 is located in an arcuate region of a neighboring arcuate wire 240. The two arcuate wires 240 support each other, thereby further improving the stability of the wires. In some other embodiments, three or more layers of wires may be provided to increase the density of the wire layers, thereby further enhancing the electromagnetic shielding effect of the Faraday cage.

In the above embodiments, the wires are arcuate wires 240. In some embodiments, the wires include vertical wires 241 extending in a direction perpendicular to the substrate 200, wherein one end of each of the vertical wires 241 is connected to the conductive dam 230, and the other end of the each of the vertical wires 241 is exposed on the surface of the molding body 250. Specifically, FIG. 8 is a top view illustrating relative positions of a conductive dam 230, wires, and a chip 210 in a package structure with electromagnetic shielding functionality according to some embodiments of the present disclosure, and FIG. 9 is a side view illustrating relative positions of a conductive dam and wires in the package structure with electromagnetic shielding functionality according to some embodiments of the present disclosure. As illustrated in FIG. 8 and FIG. 9, in these embodiments, the wires are vertical wires 241. Each of the vertical wires 241 extend in the direction perpendicular to the substrate 200 (a Z direction in FIG. 8 and FIG. 9). One end of the vertical wire 241 is connected to the conductive dam 230, and the other end of the vertical wire 241 is exposed on the surface of the molding body 250. The conductive layer 260 is in contact with and electrically connected to the other end of the vertical wire 241. In a case where the conductive dam 230 is a discontinuous structure surrounding the periphery of the chip 210, one or more vertical wires 241 may be disposed on the same sub-dam 231.

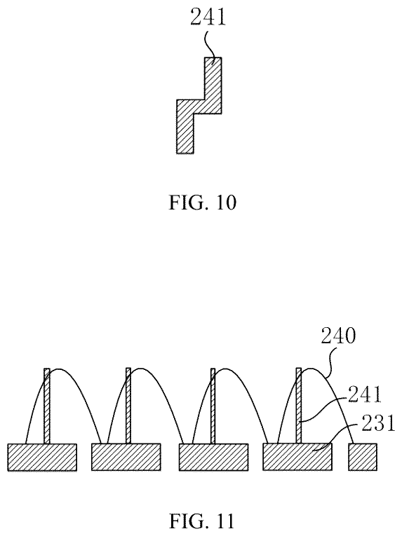

Along an extension path of the vertical wire 241, the vertical wire 241 may be a straight line, as illustrated in FIG. 9; or the vertical wire 241 may have a bend. Specifically, FIG. 10 is a schematic view of wires in a package structure with electromagnetic shielding functionality according to some embodiments of the present disclosure. As illustrated in FIG. 10, in these embodiments, the wires are vertical wires 241, and along an extension path of the vertical wires 241, each of the vertical wires 241 has a bend.

In some embodiments, the wires include arcuate wires 240, wherein both ends of each of the arcuate wires 240 are connected to the conductive dam, and a portion of the arcuate wire 240, along an extension path thereof, is exposed on the surface of the molding body 250, and the vertical wires 241 are disposed to be intersected with the arcuate wires 240 to support each other. In this way, the stability of the wires is further improved, and wire tilt or misalignment is prevented. Specifically, FIG. 11 is a side view illustrating relative position of a conductive dam and wires in a package structure with electromagnetic shielding functionality according to some embodiments of the present disclosure. As illustrated in FIG. 11, in these embodiments, the wires include vertical wires 241 and arcuate wires 240. The vertical wires 241 and the arcuate wires 240 are disposed to be intersected with each other. For example, one vertical wire 241 is positioned in an arcuate region of a neighboring arcuate wire 240. The vertical wire 241 and the arcuate wire 240 support each other, thereby further enhancing the stability of the wires. In some embodiments, a plurality of vertical wires 241 may be disposed in the arcuate region of the same arcuate wire 240 to further improve the stability of the wires and the electromagnetic shielding effect. In some embodiments, in a case where the stability of the wires and the electromagnetic shielding effect are satisfied, vertical wires 241 may be spaced apart where the span of the arcuate wires is larger. Arcuate wires with smaller spans may not have vertical wires 241 in order to save costs.

Still referring to FIG. 2, the molding body 250 covers the surface of the substrate 200, and encapsulates the chip 210, the conductive dam 230, and the wires, wherein a portion of each of the wires is exposed on the surface of the molding body 250. The molding body 250 is configured to protect the substrate 200, the chip 210, the conductive dam 230, and the wires. The conductive layer 260 is positioned outside the molding body 250. For example, in these embodiments, the conductive layer 260 covers the surface of the molding body 250. The wires, exposed in the region on the surface of the molding body 250, are in contact with the conductive layer 260, thereby achieving connection between the conductive layer 260 and the wires. In some embodiments, the conductive layer 260 only covers the entire or partial upper surface of the molding body 250. In other embodiments, the conductive layer 260 covers both the upper surface and the side surface of the molding body 250.

In the package structure according to the embodiments of the present disclosure, the height of the wires is reduced, which fundamentally improves the stability of the wires. This prevents short circuits and open circuits caused by wire tilt or misalignment, thereby greatly enhancing the reliability and electromagnetic shielding effect of the package structure.

In addition, terms “comprise,” “include,” and variations thereof used herein in the text of the present disclosure are intended to define a non-exclusive meaning. It should be noted that the terms such as “first,” “second,” and the like in the specifications, claims and the accompanying drawings of the present disclosure are intended to distinguish different objects but are not intended to define a specific order or a definite time sequence. Unless otherwise clearly indicated in the context, it should be understood that the data used in this way can be interchanged under appropriate circumstances. The term “one or more” may be used to describe a feature, structure, or characteristic in the singular, or may be used to describe a feature, structure, or combination of features in the plural, depending at least in part on the context. The term “based on” may be understood as not necessarily intended to express a set of exclusive factors, but may alternatively allow for the presence of other factors not necessarily explicitly described, again depending at least in part on the context. In cases of no conflict, the embodiments and features in the embodiments of the present disclosure may be combined together. Further, in the above description, descriptions of well-known components and techniques are omitted so as not to unnecessarily obscure the inventive concepts of the present disclosure. In various embodiments of the present disclosure, the same or similar parts between the embodiments may be referenced to each other. In each embodiment, the portion that is different from other embodiments is concentrated and described.

Described above are preferred embodiments of the present disclosure. It should be noted that persons of ordinary skill in the art may derive other improvements or refinements without departing from the principles of the present disclosure. Such improvements and refinements shall be deemed as falling within the protection scope of the present disclosure.

1. A package structure, comprising:
a substrate;
a chip, disposed on a surface of the substrate;
a conductive dam, disposed on the surface of the substrate and grounded, wherein the conductive dam surrounds a periphery of the chip;
a plurality of wires, disposed on the conductive dam;
a molding body, covering the surface of the substrate and encapsulating the chip, the conductive dam, and the plurality of wires, wherein a portion of the plurality of wires is exposed on a surface of the molding body; and
a conductive layer, positioned on the surface of the molding body and at least corresponding to the chip, wherein the conductive layer is electrically connected to the plurality of wires, wherein the conductive layer, the plurality of wires, and the conductive dam together form a Faraday cage surrounding the chip.

2. The package structure according to claim 1, wherein the conductive dam is a continuous structure.

3. The package structure according to claim 1, wherein the conductive dam is a discontinuous structure comprising a plurality of sub-dams spaced apart, wherein the plurality of wires are disposed on the plurality of sub-dams.

4. The package structure according to claim 3, wherein the plurality of sub-dams have identical or different sizes.

5. The package structure according to claim 3, wherein gaps between adjacent sub-dams are identical or different.

6. The package structure according to claim 1, wherein the chip is flip-mounted onto the surface of the substrate via conductive pillars, and a height of the conductive dam is less than a height of the conductive pillars.

7. The package structure according to claim 1, wherein the plurality of wires comprise arcuate wires, wherein both ends of the arcuate wires are connected to the conductive dam, and a portion of the arcuate wires, along an extension path thereof, is exposed on the surface of the molding body.

8. The package structure according to claim 7, wherein a plurality of the arcuate wires are arranged in a circumferential direction surrounding the chip to form a single wire layer.

9. The package structure according to claim 7, wherein a plurality of the arcuate wires are arranged in a circumferential direction surrounding the chip to form at least two wire layers, and adjacent arcuate wires in two adjacent wire layers are disposed to intersect with each other.

10. The package structure according to claim 1, wherein the plurality of wires comprise vertical wires extending in a direction perpendicular to the substrate, wherein one end of vertical wires is connected to the conductive dam, and the other end of the vertical wires is exposed on the surface of the molding body.

11. The package structure according to claim 10, wherein the plurality of wires comprise arcuate wires, wherein both ends of the arcuate wires are connected to the conductive dam, and a portion of the arcuate wires, along an extension path thereof, is exposed on the surface of the molding body, and the vertical wires are disposed to intersect with the arcuate wires.

12. The package structure according to claim 10, wherein the vertical wires has a bent portion along an extension path thereof.

13. The package structure according to claim 1, wherein the conductive dam is grounded via the substrate.
